(19) United States
(12) Patent Application Publication
(10) Pub. No.: US 2019/0371827 A1
(43) Pub. Date: Dec. 5, 2019

(54) FLEXIBLE THIN FILM TRANSISTOR AND MANUFACTURING METHOD THEREFOR

(71) Applicant: KunShan Go-Visionox Opto-Electronics Co., Ltd., Kunshan (CN)

(72) Inventors: Chunrong LAI, Kunshan (CN); Jiwen ZONG, Kunshan (CN)

(21) Appl. No.: 16/540,403

(22) Filed: Aug. 14, 2019

Related U.S. Application Data
(63) Continuation of application No. PCT/CN2018/087309, filed on May 17, 2018.

(30) Foreign Application Priority Data
Aug. 31, 2017 (CN) 201710776518.8

(51) Int. Cl. H01L 27/12; H01L 23/31; H01L 29/66

(52) U.S. Cl. CPC H01L 27/1248; H01L 23/3171; H01L 29/7866; H01L 29/66757; H01L 23/3192

(57) ABSTRACT

Embodiments of the present application disclose a flexible thin film transistor and a manufacturing method therefor. The flexible thin film transistor includes: a substrate; an active layer formed on the substrate; a gate electrode formed on the active layer; and an organic insulation layer formed on the gate electrode. In the present application, a stress of interlayer dielectric layer(s) is decreased. The overall thickness of the interlayer dielectric layer(s) is reduced, and thereby a bendability of a flexible display screen is improved.

### CROSS-REFERENCE TO RELATED APPLICATIONS

The present application is a continuation of International Application No. PCT/CN2018/087309 filed on May 17, 2018, which claims priority to Chinese patent application No. 201710776518.8 filed on Aug. 31, 2017. Both applications are incorporated herein by reference in their entireties.

### TECHNICAL FIELD

The present application relates to the field of display technologies, particularly to a flexible Thin Film Transistor (TFT) and a manufacturing method therefor.

### BACKGROUND

With the development of flexible display technologies, a display screen has already been made into a flexible, foldable or rollable form. A flexible display screen which is variable and bendable can bring a disruptive experience for users. However, the current flexible display technologies are not mature enough, and the bendability is still a technical difficulty. This is because there are more inorganic insulation layers in a pixel region of a flexible display screen, and the inorganic insulation layers are relatively thick. Thus a larger stress is generated when the flexible display screen is deformed, a bendability of the flexible display screen is directly affected, and thereby a poor display is caused.

The thin film transistor includes: a substrate; an active layer formed on the substrate; a source electrode and a drain electrode electrically connected with the active layer; a gate insulation layer formed on the active layer; a gate electrode formed on the gate insulation layer; a capacitance insulation layer formed on the gate electrode; and a first interlayer dielectric layer and a second interlayer dielectric layer formed on the capacitance insulation layer in sequence. The thickness of the gate insulation layer and that of the capacitance insulation layer are 120 nm, respectively. The overall thickness of the first interlayer dielectric layer and the second interlayer dielectric layer is substantially 500 nm.

The first interlayer dielectric layer and the second interlayer dielectric layer are disposed between two layers and used for performing an insulation between the two layers, respectively. When the overall thickness of the two layers is thicker than the thickness of other insulation layers, a bendability of the thin film transistor may become worse. In addition, the gate insulation layer, the capacitance insulation layer, the first interlayer dielectric layer and the second interlayer dielectric layer are inorganic insulation layers which are made of inorganic materials having relatively poor elasticity and flexibility, therefore the bendable degree of the thin film transistor becomes worse.

### SUMMARY

In view of this, embodiments of the present application provide a flexible thin film transistor and a manufacturing method therefor so as to improve a bendability of a flexible display screen.

An aspect of the present application provides a flexible thin film transistor. The flexible thin film transistor includes: a substrate; an active layer formed on the substrate; a gate electrode formed on the active layer; and an organic insulation layer formed on the gate electrode.

In an embodiment of the present application, the flexible thin film transistor further includes an inorganic insulation layer formed on the organic insulation layer.

In an embodiment of the present application, a material of the organic insulation layer is organic glue and/or polyimide.

In an embodiment of the present application, the organic insulation layer is further doped with an inorganic material.

In an embodiment of the present application, a thickness of the inorganic insulation layer is within a range of 45 nm to 55 nm.

In an embodiment of the present application, the thickness of the inorganic insulation layer is 50 nm.

In an embodiment of the present application, a thickness of the organic insulation layer is within a range of 300 nm to 450 nm.

In an embodiment of the present application, the thickness of the organic insulation layer is 350 nm.

In an embodiment of the present application, the flexible thin film transistor further includes: a buffer layer formed between the substrate and the active layer; a gate insulation layer formed between the active layer and the gate electrode; and a capacitance insulation layer formed between the gate electrode and the organic insulation layer.

Another aspect of the present application provides a manufacturing method for a flexible thin film transistor. The manufacturing method for the flexible thin film transistor includes: forming an active layer on a substrate; forming a gate electrode on the active layer; and forming an organic insulation layer on the gate electrode.

In an embodiment of the present application, the manufacturing method for the flexible thin film transistor further includes: forming an inorganic insulation layer on the organic insulation layer.

In an embodiment of the present application, the forming an inorganic insulation layer on the organic insulation layer includes: depositing a thin layer of the inorganic insulation layer on the organic insulation layer by chemical vapor deposition or film formation; exposuring, developing and etching the inorganic insulation layer; and depositing a metal onto the organic insulation layer by physical vapor deposition.

In an embodiment of the present application, the forming an active layer on a substrate includes: forming at least one buffer layer on the substrate; and disposing the active layer on the at least one buffer layer.

In an embodiment of the present application, the forming an organic insulation layer on the gate electrode includes: forming a capacitance insulation layer on the gate electrode; forming a capacitance metal on the capacitance insulation layer; and forming the organic insulation layer on the capacitance metal.

According to technical solutions provided by the embodiments of the present application, by replacing interlayer dielectric layer(s) in the prior art with an organic insulation layer, a stress of the interlayer dielectric layer(s) is decreased, the overall thickness of the interlayer dielectric layer(s) is reduced, and thereby a bendability of a flexible display screen is improved.

It should be understood that the above general descriptions and the following detailed descriptions are merely exemplary and explanatory, and are not intended to limit the present application.

### BRIEF DESCRIPTION OF DRAWINGS

Accompanying drawings herein, which are incorporated into the specification and constitute a part of the specification, illustrate embodiments conforming to the present application, and are configured to explain the principles of the present application together with the specification.

FIG. 1 is a schematic structural diagram illustrating a flexible thin film transistor according to an exemplary embodiment of the present application.

FIG. 2 is a schematic structural diagram illustrating a flexible thin film transistor according to another exemplary embodiment of the present application.

FIG. 3 is a schematic flowchart illustrating a manufacturing method for a flexible thin film transistor according to an exemplary embodiment of the present application.

FIG. 4 is a schematic flowchart illustrating a manufacturing method for a flexible thin film transistor according to another exemplary embodiment of the present application.

### DETAILED DESCRIPTION

A clear and complete description of technical solutions in the embodiments of the present application will be given below, in combination with the accompanying drawings in the embodiments of the present application. Obviously, described embodiments are only a part of embodiments of the present application, and are not all embodiments. All other embodiments obtained by those skilled in the art based on the embodiments of the present application without creative efforts, shall fall within the protection scope of the present application.

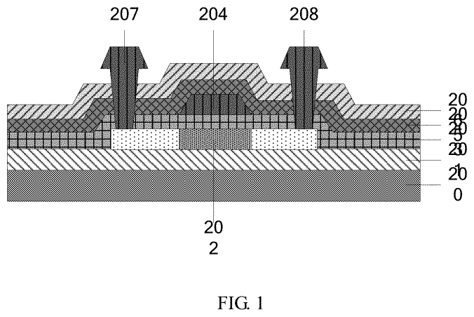

FIG. 1 is a schematic structural diagram illustrating a flexible thin film transistor according to an exemplary embodiment of the present application. As shown in FIG. 1, the flexible thin film transistor includes: a substrate 200; an active layer 202 formed on the substrate; a gate electrode 204 formed on the active layer 202; and an organic insulation layer 206 formed on the gate electrode 204.

In the embodiments of the present application, the substrate 200 usually is a transparent glass substrate, or may be other transparent substrate, such as a transparent plastic substrate. It is not limited by the present application.

A material of the active layer 202 may be one of polysilicon (p-Si) and amorphous silicon (a-Si). In the embodiment, polysilicon is preferred. Compared to the amorphous silicon, the electron migration rate of polysilicon is faster and the stability of polysilicon is higher. The area of a thin film circuit may be reduced, and the resolution of a display screen may be improved. The thickness of the active layer 202 is usually within a range of 20 nm to 50 nm, preferably 45 nm.

A material of the gate electrode 204 may be a combination of one or more of molybdenum (Mo), titanium (Ti), aluminum (Al), copper (Cu), gold (Au) and silver (Ag). The thickness of the gate electrode 204 is usually within a range of 200 nm to 300 nm, preferably 250 nm.

The thickness of the organic insulation layer 206 may be within a range of 300 nm to 450 nm, preferably 350 nm.

According to technical solutions provided by embodiments of the present application, by replacing interlayer dielectric layer(s) with an organic insulation layer, a stress of the interlayer dielectric layer(s) is decreased, the overall thickness of the interlayer dielectric layer(s) is reduced, and thereby a bendability of a flexible display screen is improved.

In another embodiment of the present application, the flexible thin film transistor further includes an inorganic insulation layer (not shown) formed on the organic insulation layer 206.

Specifically, a material of the inorganic insulation layer may be one of silicon oxide (SiOx) and silicon nitride (SiNx), or a combination thereof. In addition, the inorganic insulation layer is thin and the thickness thereof is within a range of 45 nm to 55 nm, preferably 50 nm. In the embodiments of the present application, considering that the insulating property of the organic insulation layer is far weaker than that of the inorganic insulation layer, the insulating property of a thin film transistor may be more effectively improved by arranging a thin layer of the inorganic insulation layer on the organic insulation layer 206. Additionally, since the thickness of the inorganic insulation layer is only 50 nm and is very thin, so that there is no significant influence on the overall thickness of the thin film transistor. Furthermore, the overall thickness of the organic insulation layer 206 and the inorganic insulation layer in the embodiments of the present application is within a range of 345 nm to 505 nm, preferably 400 nm, which is significantly smaller than the overall thickness of 500 nm of the first interlayer dielectric layer and the second interlayer dielectric layer, therefore the production cost of the thin film transistor is saved.

In another embodiment of the present application, a material of the organic insulation layer 206 is one of organic glue and polyimide.

Specifically, the material of the organic insulation layer 206 may be one of organic glue and Polyimide (PI) having high electrical resistivity, high strength, high toughness, high insulating property, wear resistance, high temperature resistance and corrosion resistance. Since the organic glue or PI has high electrical resistivity, high toughness and high insulating property, a stress of the interlayer dielectric layer(s) is reduced, and thereby the bendable degree of the flexible display screen is improved.

In another embodiment of the present application, the organic insulation layer 206 is further doped with an inorganic material.

Specifically, particles/pellets of the inorganic material (such as silicon oxide, silicon nitride or the like) may be doped in the organic glue or PI of the organic insulation layer 206, or may be arranged on the organic glue or PI, which is not limited by the present application. In the embodiment of the present application, by doping the inorganic material into the organic insulation layer 206, the insulating property of the organic insulation layer 206 can be further improved, and therefore the inorganic insulation layer disposed on the organic insulation layer 206 may be omitted. Furthermore, the production cost of the thin film transistor is saved.

In another embodiment of the present application, the flexible thin film transistor further includes: a buffer layer 201 formed between the substrate 200 and the active layer 202; a gate insulation layer 203 formed between the active layer 202 and the gate electrode 204; and a capacitance insulation layer 205 formed between the gate electrode 204 and the organic insulation layer 206.

Specifically, a material of the buffer layer 201 may be one of, or a combination of silicon oxide and silicon nitride. In addition, the thickness of the buffer layer 201 is generally within a range of 200 nm to 300 nm, preferably 250 nm. It should be noted that the number of layers of the buffer layer 201 may be set according to actual requirements, for example, two layers, three layers or the like, which is not limited by the present application.

A material of the gate insulation layer 203 may be one of, or a combination of silicon oxide and silicon nitride. The thickness of the gate insulation layer 203 may be within a range of 100 nm to 150 nm, preferably 120 nm.

The capacitance insulation layer 205 may be formed between the gate electrode 204 and the organic insulation layer 206. The thickness of the capacitance insulation layer 205 may be within a range of 100 nm to 150 nm, preferably 120 nm.

Further, a source electrode 207 and a drain electrode 208 are formed on the buffer layer 201, and are electrically connected with the active layer 202, respectively. A material of the source electrode 207 and the drain electrode 208 may be a combination of one or more of Mo, Ti, Al, Cu, Au and Ag. In addition, the thickness of the gate electrode 204 is generally within a range of 200 nm to 300 nm, preferably 250 nm.

All of the foregoing alternative technical solutions may be combined by any ways to form alternative embodiments of the present application, which are not further described herein.

FIG. 2 is a schematic structural diagram illustrating a flexible thin film transistor according to another exemplary embodiment of the present application. As shown in FIG. 2, the flexible thin film transistor includes: a substrate 300; a first buffer layer 301 formed on the substrate 300; a second buffer layer 302 formed on the first buffer layer 301; an active layer 303 formed on the second buffer layer 302; a gate insulation layer 304 formed on the active layer 303; a gate electrode 305 formed on the gate insulation layer 304; a capacitance insulation layer 306 formed on the gate electrode 305; an organic insulation layer 307 formed on the capacitance insulation layer 306; and an inorganic insulation layer 308 formed on the organic insulation layer 307.

It should be noted that a structure of the flexible thin film transistor shown in FIG. 2 is substantially the same as that of the flexible thin film transistor shown in FIG. 1. Therefore, the following will only illustrate the differences.

In the embodiments of the present application, the first buffer layer 301 and the second buffer layer 302 may be formed on the substrate 300 in sequence. A material of the first buffer layer 301 and the second buffer layer 302 may be one of, or a combination of silicon oxide and silicon nitride. Specifically, the material of the first buffer layer 301 is silicon nitride, and the thickness of the first buffer layer 301 is generally within a range of 45 nm to 55 nm, preferably 50 nm. The material of the second buffer layer 302 is silicon oxide, and the thickness thereof is generally within a range of 200 nm to 300 nm, preferably 250 nm. It should be noted that the material of the first buffer layer 301 and the second buffer layer 302 may also be one of organic glue, PI, organic glue doped with an inorganic material and PI doped with an inorganic material. That is, in order to improve a bendability of a thin film transistor, any one or two of the first buffer layer 301 and the second buffer layer 302 may also be prepared as organic insulation layers.

A material of the gate insulation layer 304 may be one of silicon oxide and silicon nitride, or a combination thereof. It should be noted that the material of the gate insulation layer 304 may also be one of organic glue, PI, organic glue doped with an inorganic material and PI doped with an inorganic material. That is, in order to improve the bendable degree of the thin film transistor, the gate insulation layer 304 may also be prepared as an organic insulation layer.

A material of the capacitance insulation layer 306 may be one of, or a combination of silicon oxide and silicon nitride. It should be noted that the material of the capacitance insulation layer 306 may also be one of organic glue, PI, organic glue doped with an inorganic material and PI doped with an inorganic material. That is, in order to improve the bendable degree of the thin film transistor, the capacitance insulation layer 306 may also be prepared as an organic insulation layer.

A material of the inorganic insulation layer 308 may be one of, or a combination of silicon oxide and silicon nitride. In addition, the inorganic insulation layer 308 is very thin, and the thickness thereof is within a range of 45 nm to 55 nm, preferably 50 nm. In the embodiments of the present application, considering that the insulating property of the organic insulation layer is far less than that of the inorganic insulation layer, the insulating property of the thin film transistor may be more effectively improved by arranging a thin layer of the inorganic insulation layer 308 on the organic insulation layer 307. Additionally, since the thickness of the inorganic insulation layer 308 is only 50 nm and is very thin, so that there is no significant influence on the overall thickness of the thin film transistor. Further, the overall thickness of the organic insulation layer 307 and the inorganic insulation layer 308 in the embodiments of the present application is within a range of 345 nm to 505 nm, preferably 400 nm, which is significantly smaller than the overall thickness 500 nm of the first interlayer dielectric layer and the second interlayer dielectric layer, therefore the production cost of the thin film transistor is saved.

According to technical solutions provided by the embodiments of the present application, by replacing interlayer dielectric layer(s) with an organic insulation layer and a very thin inorganic insulation layer, the overall stress of the interlayer dielectric layer(s) is decreased, and a bendability of a flexible display screen is improved.

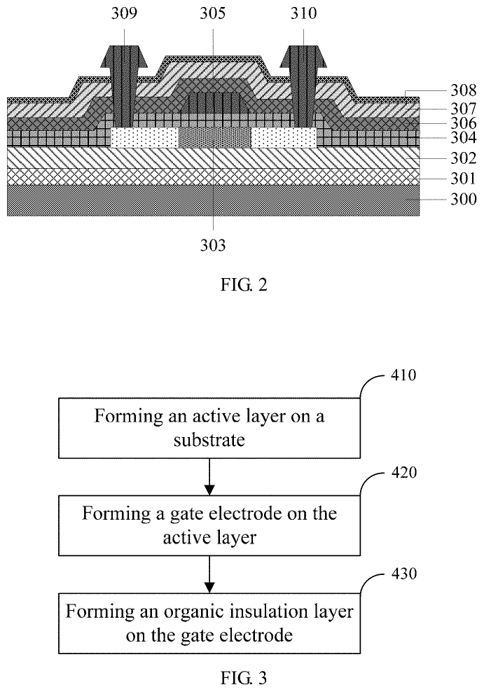

FIG. 3 is a schematic flowchart illustrating a manufacturing method for a flexible thin film transistor according to an exemplary embodiment of the present application. As shown in FIG. 3, the manufacturing method for the flexible thin film transistor includes the following steps.

410: forming an active layer on a substrate.

420: forming a gate electrode on the active layer.

430: forming an organic insulation layer on the gate electrode.

According to technical solutions provided by the embodiments of the present application, by replacing interlayer dielectric layer(s) with an organic insulation layer, a stress of the interlayer dielectric layer(s) is decreased, the overall thickness of the interlayer dielectric layer(s) is reduced, and thereby a bendability of a flexible display screen is improved.

In another embodiment of the present application, the manufacturing method for the flexible thin film transistor further includes: forming an inorganic insulation layer on the organic insulation layer.

In another embodiment of the present application, the manufacturing method for the flexible thin film transistor further includes: forming a buffer layer between the substrate and the active layer; forming a gate insulation layer between the active layer and the gate electrode; and forming a capacitance insulation layer between the gate electrode and the organic insulation layer.

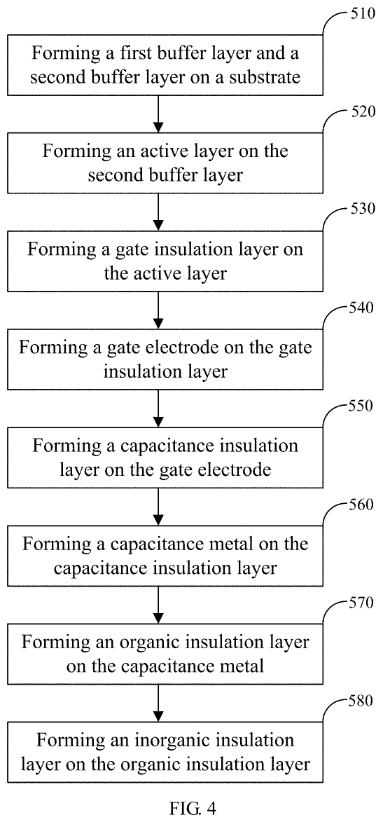

FIG. 4 is a schematic flowchart illustrating a manufacturing method for a flexible thin film transistor according to another exemplary embodiment of the present application. As shown in FIG. 4, the manufacturing method for the flexible thin film transistor includes the following steps.

510: forming a first buffer layer and a second buffer layer on a substrate.

In the embodiments of the present application, the first buffer layer and the second buffer layer are sequentially formed on one of a cleaned glass substrate and a plastic substrate by a Chemical Vapor Deposition (CVD) method. The first buffer layer and the second buffer layer may be a silicon oxide layer, a silicon nitride layer, or a composite layer of a silicon oxide layer and a silicon nitride layer. In the embodiment, the first buffer layer is the silicon nitride layer and the second buffer layer is the silicon oxide layer.

520: forming an active layer on the second buffer layer.

In the embodiments of the present application, the active layer is formed on the second buffer layer by the CVD method. A material of the active layer is amorphous silicon. Subsequently, the amorphous silicon is converted to polysilicon by an Excimer Laser Anneal (ELA) process.

530: forming a gate insulation layer on the active layer.

In the embodiments of the present application, the gate insulation layer is formed on the active layer by a Plasma Enhanced Chemical Vapor Deposition (PECVD) method.

The second buffer layer is covered by the gate insulation layer.

540: forming a gate electrode on the gate insulation layer.

In the embodiments of the present application, the gate electrode directly above the active layer, that is, a first metal M1, is formed on the gate insulation layer by a Physical Vapor Deposition (PVD) method. Furthermore, boron ion implantation is performed on both ends of the active layer to form a source electrode and a drain electrode.

550: forming a capacitance insulation layer on the gate electrode.

In the embodiments of the present application, the capacitance insulation layer is formed on the gate electrode by CVD or film formation. The gate insulation layer is covered by the capacitance insulation layer.

560: forming a capacitance metal on the capacitance insulation layer.

In the embodiments of the present application, the capacitance metal, i.e., a second metal M2, is formed on the capacitance insulation layer by PVD or film formation.

570: forming an organic insulation layer on the capacitance metal.

In the embodiments of the present application, the organic insulation layer is formed on the capacitance metal by coating one of organic glue and PI, and the organic insulation layer is exposed and developed.

580: forming an inorganic insulation layer on the organic insulation layer.

In the embodiments of the present application, a thin layer of the inorganic insulation layer is deposited on the organic insulation layer by CVD or film formation, and the inorganic insulation layer is exposed, developed and etched. Further, a third metal M3 is deposited on the organic insulation layer by PVD.

Finally, the glass substrate or the plastic substrate is separated from the thin film transistor.

It should be noted that a material of the first metal M1, the second metal M2 and the third metal M3 may be one of, or a combination of Mo, Ti, Al, Cu, Au and Ag.

According to technical solutions provided by the embodiments of the present application, by replacing interlayer dielectric layer(s) with an organic insulation layer and a very thin inorganic insulation layer, the overall stress of the interlayer dielectric layer(s) is decreased, and a bendability of a flexible display screen is improved.

The above are only preferred embodiments of the present application, which are not intended to limit the present application. Any modifications, equivalent substitutions and the like made within the spirit and principle of the present application should be included within the protection scope of the present application.

What is claimed is:

1. A flexible thin film transistor, comprising:
a substrate;
an active layer formed on the substrate;
a gate electrode formed on the active layer; and
an organic insulation layer formed on the gate electrode.

2. The flexible thin film transistor according to claim 1, further comprising:
an inorganic insulation layer formed on the organic insulation layer.

3. The flexible thin film transistor according to claim 1, wherein a material of the organic insulation layer is organic glue and/or polyimide.

4. The flexible thin film transistor according to claim 3, wherein the organic insulation layer is further doped with an inorganic material.

5. The flexible thin film transistor according to claim 2, wherein a thickness of the inorganic insulation layer is within a range of 45 nm to 55 nm.

6. The flexible thin film transistor according to claim 5, wherein the thickness of the inorganic insulation layer is 50 nm.

7. The flexible thin film transistor according to claim 1, wherein a thickness of the organic insulation layer is within a range of 300 nm to 450 nm.

8. The flexible thin film transistor according to claim 7, wherein the thickness of the organic insulation layer is 350 nm.

9. The flexible thin film transistor according to claim 1, further comprising:
a buffer layer formed between the substrate and the active layer;
a gate insulation layer formed between the active layer and the gate electrode; and
a capacitance insulation layer formed between the gate electrode and the organic insulation layer.

10. A manufacturing method, for manufacturing a flexible thin film transistor, comprising:
forming an active layer on a substrate;
forming a gate electrode on the active layer; and
forming an organic insulation layer on the gate electrode.

11. The manufacturing method according to claim 10, further comprising:
forming an inorganic insulation layer on the organic insulation layer.

12. The manufacturing method according to claim 11, wherein forming the inorganic insulation layer comprises:
depositing a thin layer of the inorganic insulation layer on the organic insulation layer by chemical vapor deposition or film formation;
exposuring, developing and etching the inorganic insulation layer; and
depositing a metal onto the organic insulation layer by physical vapor deposition.

13. The manufacturing method according to claim 10, wherein the forming an active layer on a substrate comprises:
forming at least one buffer layer on the substrate; and
disposing the active layer on the at least one buffer layer.

14. The manufacturing method according to claim 10, wherein the forming an organic insulation layer on the gate electrode comprises:
forming a capacitance insulation layer on the gate electrode;
forming a capacitance metal on the capacitance insulation layer; and
forming the organic insulation layer on the capacitance metal.
